(19) United States
(12) Patent Application Publication
(10) Pub. No.: US 2012/0220132 A1
(43) Pub. Date: Aug. 30, 2012

(54) SEMICONDUCTOR DEVICE MANUFACTURING METHOD

(75) Inventors: Kenichi OYAMA, Nirasaki City (JP); Shohei YAMAUCHI, Nirasaki City (JP); Hidetami YAEGASHI, Tokyo (JP)

(73) Assignee: TOKYO ELECTRON LIMITED, Tokyo (JP)

(21) Appl. No.: 13/403,604

(22) Filed: Feb. 23, 2012

(30) Foreign Application Priority Data
Feb. 25, 2011 (JP) 2011-039163

(51) Int. Cl. H01L 21/32

(52) U.S. Cl. 438/703; 257/E21.258

(57) ABSTRACT

A semiconductor device manufacturing method includes: forming a core layer, an anti-reflection film and a photoresist layer on a layer to be etched of a substrate; trimming first line patterns of the photoresist layer; forming a first film on the first line patterns; removing the first film such that the first film is left in sidewall portions of the first line patterns of the photoresist layer; removing the photoresist layer; producing the core layer into second line patterns by etching the anti-reflection film and the core layer; forming a second film on the core layer produced into the second line patterns; removing the second film such that the second film is left in sidewall portions of the second line patterns of the core layer; and producing the layer to be etched into third line patterns by etching the layer to be etched.

### CROSS-REFERENCE TO RELATED APPLICATIONS

This application claims the benefit of Japanese Patent Application No. 2011-039163, filed on Feb. 25, 2011, in the Japan Patent Office, and the disclosure of which is incorporated herein in its entirety by reference.

### TECHNICAL FIELD

The present disclosure relates to a semiconductor device manufacturing method.

### BACKGROUND

In a semiconductor device manufacturing process, fine circuit patterns have heretofore been formed by a photolithography technology using a photoresist. A side wall transfer (SWT) process or a double patterning (DP) process has been studied in an effort to further miniaturize circuit patterns.

A technology of transferring an initially-formed photoresist pattern to a hard mask is one example of the miniaturizing technology used in the photolithography. In this technology, the hard mask is used together with a resist mask.

Also, in the related art, to miniaturize circuit patterns, the following technologies are also developed: a technology of trimming a photoresist line pattern; a technology of forming a silicon dioxide film as a first spacer layer; a technology of forming a ½ pitch pattern by etching the silicon dioxide film so that the silicon dioxide film can be left only in sidewall portions of the photoresist line pattern; a technology of forming the silicon nitride film as a second spacer layer on the silicon dioxide film; and a technology of forming a ¼ pitch pattern formed of a silicon nitride film.

In the technology of forming the ¼ pitch pattern in this manner, the silicon dioxide film is formed on the photoresist pattern and is left in the sidewall portions of the photoresist pattern. Such silicon dioxide film is used as a core and the silicon nitride film is formed on the silicon dioxide film as a second spacer layer. However, the pattern of the silicon dioxide film left on the sidewall portions of the photoresist pattern is formed into a so-called claw-like shape, i.e., a shape in which one of the upper end portions is curved. The upper surface of the pattern of the silicon dioxide film has a non-flat shape. However, the use of the pattern as the core controllability deteriorates the line width. In order to avoid such problem, a multiple number of core layers to be etched through a mask may be formed on a layer to be etched beforehand. This however poses a problem of an increased number of steps to manufacture a semiconductor device and a higher manufacturing cost.

For the reasons stated above, the advent of a technology capable of accurately forming a desired fine pattern in an efficient manner is required in the miniaturizing technology used in the photolithography.

### SUMMARY

The present disclosure provides a semiconductor device manufacturing method capable of accurately forming a desired fine pattern in a more efficient manner than in the prior art and capable of enhancing the production efficiency of a semiconductor device.

According to one embodiment of the present disclosure, there is provided a semiconductor device manufacturing method forming a core layer, an anti-reflection film and a photoresist layer on a layer to be etched of a substrate with the core layer below the anti-reflection film and the photoresist layer over the anti-reflection film, the photoresist layer being patterned into first line patterns aligned at a desired interval, trimming the first line patterns of the photoresist layer, forming a first film on the first line patterns of the trimmed photoresist layer, removing the first film such that the first film is left in sidewall portions of the first line patterns of the photoresist layer, removing the photoresist layer, producing the core layer into second line patterns by etching the anti-reflection film and the core layer using the first film as a mask, forming a second film on the core layer produced into the second line patterns, removing the second film such that the second film is left in sidewall portions of the second line patterns of the core layer, and producing the layer to be etched into third line patterns by etching the layer to be etched using the second film as a mask.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1H illustrates views for explaining steps of one embodiment of a semiconductor device manufacturing method according to the present disclosure.

FIG. 2 is a flowchart illustrating steps of the semiconductor device manufacturing method shown in FIGS. 1A to 1H.

### DETAILED DESCRIPTION

Reference will now be made in detail to various embodiments, examples of which are illustrated in the accompanying drawings. In the following detailed description, numerous specific details are set forth in order to provide a thorough understanding of the present invention(s). However, it will be apparent to one of ordinary skill in the art that the present invention(s) may be practiced without these specific details. In other instances, well-known methods, procedures, systems, and components have not been described in detail so as not to unnecessarily obscure aspects of the various embodiments.

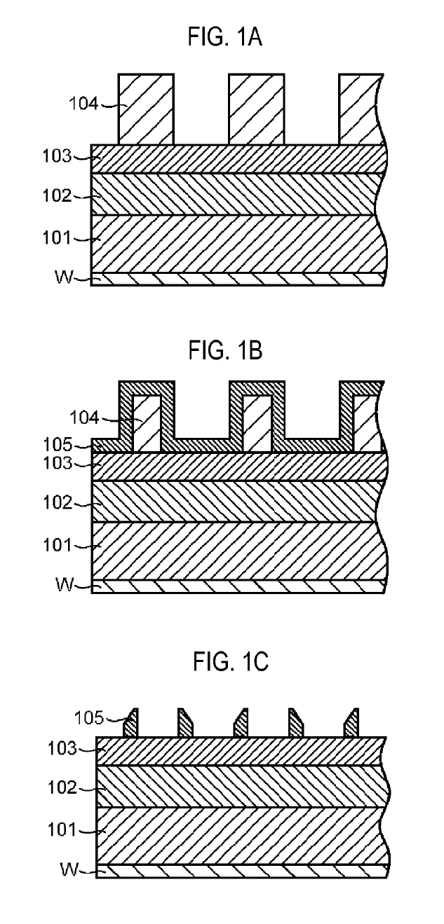

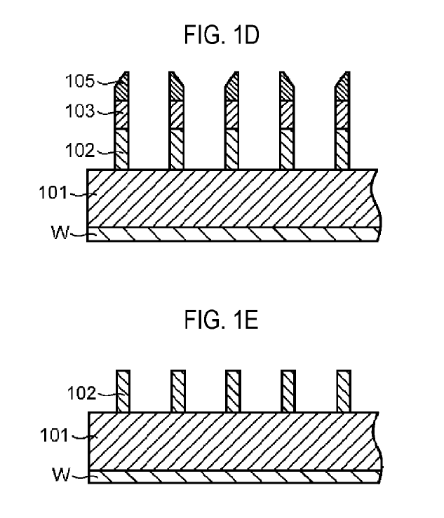

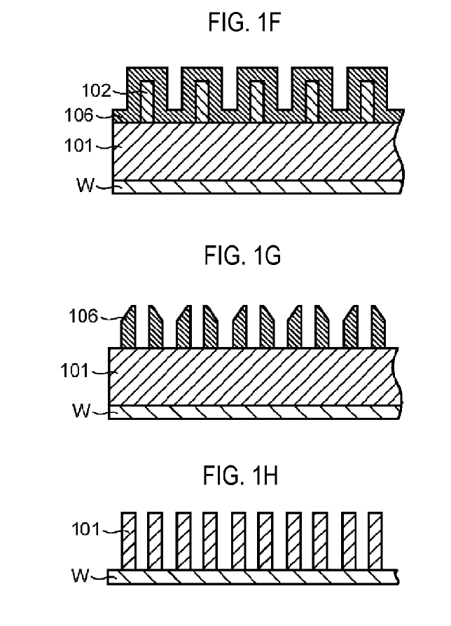

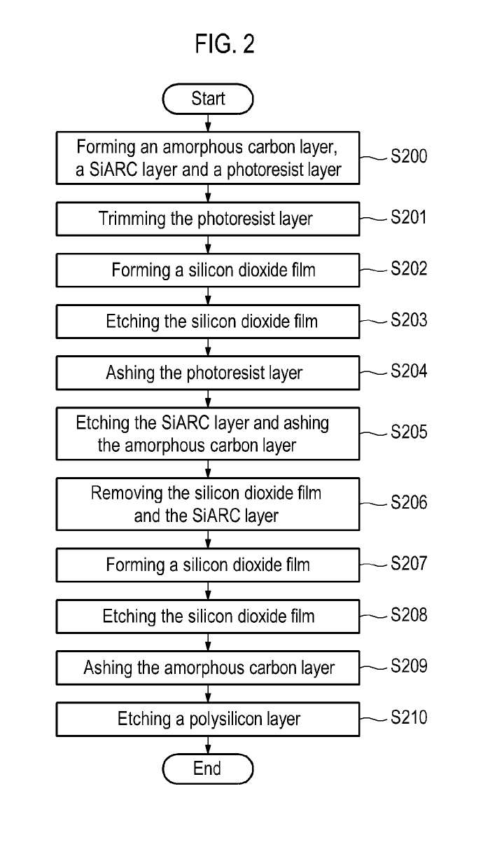

FIGS. 1A to 1H illustrate enlarged schematic views of a portion of a semiconductor wafer as a substrate according to one embodiment of the present disclosure. Further, FIGS. 1A to 1H illustrate steps of a semiconductor device manufacturing method according to one embodiment of the present disclosure. FIG. 2 is a flowchart illustrating steps of the semiconductor device manufacturing method according to one embodiment of the present disclosure.

Referring to FIG. 1A, a polysilicon layer 101 corresponds to a layer to be etched and is formed on a semiconductor wafer W. In the embodiment, an amorphous carbon layer 102 is first formed on the polysilicon layer 101. The amorphous carbon layer 102 corresponds to a carbon layer and will become a core layer. A SiARC layer (anti-reflection film) 103 is formed on top of the amorphous carbon layer 102. A photoresist layer 104 having a desired line-and-space pattern is formed on the SiARC layer 103 (step S200 in FIG. 2).

The photoresist layer 104 is formed through steps such as applying, exposing and developing a photoresist. The exposing step can be performed by, e.g., an ArF immersion exposure. In place of the amorphous carbon layer 102, it may be possible to use a coating film (spin-on carbon film) which can be formed by a spin coat. However, the coating film (spin-on carbon film) has lower in strength than the amorphous carbon layer 102. Nonetheless, using the coating film (spin-on carbon film) enables a coater for coating the photoresist layer 104 to coat and to form the coating film prior to coating the photoresist layer 104. Thus, the steps from the formation of the coating film to the formation of the photoresist layer 104 can be successively performed within one and the same apparatus, which assists in simplifying the process.

As shown in FIG. 1A, first, the photoresist layer 104 is trimmed to reduce the line width of the photoresist layer 104 (step S201 in FIG. 2). Thereafter, a silicon dioxide (SiO₂) film 105 corresponding to a first film is formed on the photoresist layer 104 as shown in FIG. 1B (step S202 in FIG. 2). The thickness of the silicon dioxide (SiO₂) film 105 corresponding to the first film may be about 20 nm.

The trimming of the photoresist layer 104 can be performed by, e.g., treating oxygen plasma within a plasma CVD apparatus for forming the silicon dioxide film 105. When forming the silicon dioxide film 105, it is preferable to use a MLD (Molecular Layer Deposition) method so that the silicon dioxide film 105 can be formed at a low temperature (i.e., 140 degrees C. or less). Further, it may be possible to use films made of other materials in place of silicon dioxide film 105, as long as they can be formed at a temperature lower than the glass transition temperature of the photoresist at which no damage is done to the photoresist in a film forming process. It may be possible to use films made of, e.g., aluminum oxide (AlₓO_{y}), aluminum nitride (AlN), titanium oxide (TiOₓ), silicon nitride (SiN), amorphous silicon and polysilicon.

Next, the silicon dioxide film 105 is etched so that the silicon dioxide film 105 can be left only in sidewall portions of the photoresist layer 104 (step S203 in FIG. 2). Thereafter, the photoresist layer 104 is removed by ashing and has a so-called claw-like shape, as shown in FIG. 1C (step S204 in FIG. 2).

The etching of the silicon dioxide film 105 can be performed by using, e.g., a parallel plate type plasma etching apparatus that performs plasma etching using an etching gas such as CF₄ or Ar. The ashing of the photoresist layer 104 can be performed by using the same etching apparatus that performs the ashing operation using oxygen gas plasma.

Next, the SiARC layer 103 is etched using the silicon dioxide film 105 that corresponds to a mask. Subsequently, the amorphous carbon layer 102 is subjected to ashing as shown in FIG. 1D (step S205 in FIG. 2).

The etching of the SiARC layer 103 can be performed by using, e.g., a parallel plate type plasma etching apparatus that performs plasma etching using an etching gas such as CF₄ or Ar. The ashing of the amorphous carbon layer 102 can be performed through the use of the same etching apparatus that performs ashing using oxygen gas plasma. Thus, from the etching of the silicon dioxide film 105 to the ashing of the amorphous carbon layer 102 can be successively performed using the same etching apparatus without having to unload the semiconductor wafer W from a processing chamber.

Next, the SiARC layer 103 and the silicon dioxide film 105 remaining on the amorphous carbon layer 102 are removed as shown in FIG. 1E (step S206 in FIG. 2).

The removal of the SiARC layer 103 and the silicon dioxide film 105 can be performed by, e.g., a gas chemical etching apparatus using a processing gas such as HF, NH₃, or Ar.

Next, a silicon dioxide (SiO₂) film 106 as a second film is formed on the amorphous carbon layer 102 as shown in FIG. 1F (step S207 in FIG. 2). The thickness of the silicon dioxide film 106 corresponding to the second film may be about 12 nm.

In forming the silicon dioxide film 106, it is preferable to use the MLD (Molecular Layer Deposition) method by which the silicon dioxide film 106 can be formed at a low temperature (i.e., 140 degrees C. or less).

Next, the silicon dioxide film 106 is etched so that the silicon dioxide film 106 can be left only in sidewall portions of the amorphous carbon layer 102 (step S208 in FIG. 2). Thereafter, the amorphous carbon layer 102 is removed by ashing and has a so-called claw-like shape, as shown in FIG. 1G (step S209 in FIG. 2).

The etching of the silicon dioxide film 106 can be performed by using, e.g., a parallel plate type plasma etching apparatus that performs plasma etching using an etching gas such as CF₄ or Ar. The ashing of the amorphous carbon layer 102 can be performed by using the same etching apparatus that performs ashing using oxygen gas plasma.

Next, the polysilicon layer 101 is etched using the silicon dioxide film 106 corresponding to a mask, thereby forming the polysilicon layer 101 into a line-and-space pattern. Thereafter, the silicon dioxide film 106 is removed as shown in FIG. 1H (step S210 in FIG. 2). The line-and-space pattern of the polysilicon layer 101 has a pitch equal to ¼ of the pitch of the line-and-space pattern of the photoresist layer 104 as shown in FIG. 1A. This means that, if the line-and-space pattern of the photoresist layer 104 has a half pitch of, e.g., 40 nm, the half pitch of the line-and-space pattern of the polysilicon layer 101 becomes equal to 10 nm.

The etching of the silicon dioxide film 106 can be performed through the use of, e.g., a parallel plate type plasma etching apparatus that performs plasma etching using an etching gas such as Cl₂, Ar, or N₂. Alternatively, the etching of the silicon dioxide film 106 may be performed by using, e.g., a parallel plate type plasma etching apparatus that performs plasma etching using an etching gas such as CF₄ or Ar.

As described above, there is no such case in the present embodiment that a film is formed on a so-called claw-like pattern of silicon dioxide, as a core, which is formed in sidewall portions of a line-and-space pattern. This makes it possible to secure enhanced line width controllability. Moreover, a ¼ pitch pattern can be obtained by performing double patterning twice using a laminated structure in which only three layers, i.e., the amorphous carbon layer 102, the SiARC layer 103 and the photoresist layer 104, are deposited on the polysilicon layer 101 corresponding to a layer to be etched. This makes it possible to restrain an increase in the number of steps and to reduce the manufacturing cost.

In one embodiment, a line-and-space pattern of polysilicon having a pitch equal to ¼ of an initial photoresist pattern was formed by performing double patterning twice under the following processing conditions.

### Trimming of Photoresist

The trimming of the photoresist was performed under the treatment of oxygen plasma in a batch-type film forming apparatus. The processing conditions are as follows:

pressure: 20 Pa (150 mTorr)

high-frequency power: 50 W

processing gas: O₂=1000 sccm

rotation speed: 2.0 rpm

time: 15.0 minutes

### Formation of Silicon Dioxide Film (First Film)

The formation of the silicon dioxide film (first film) was performed at a temperature of 140 degrees C. or less by the batch-type film forming apparatus used in the photoresist trimming and through the use of the MLD (Molecular Layer Deposition) method. The silicon dioxide film has a thickness of 20 nm.

### Etching of Silicon Dioxide Film (First Film)

The etching of the silicon dioxide film (first film) was performed through the use of a single-wafer-type CCP etching apparatus that generates plasma by applying a high-frequency power to between an upper electrode and a lower electrode. The processing conditions are as follows:

pressure: 2.66 Pa (20 mTorr)

high-frequency power (upper/lower electrodes): 600 W/100 W

processing gas: CF₄/Ar=100/200 sccm

time: 30.0 seconds

### Ashing of Photoresist

The ashing of the photoresist was successively performed using the single-wafer-type CCP etching apparatus used in the etching of the silicon dioxide film (first film). The processing conditions are as follows:

pressure: 2.66 Pa (20 mTorr)

high-frequency power (upper/lower electrodes): 600 W/100 W

processing gas: O₂=350 sccm

time: 15.0 seconds

### Etching of SiARC

The etching of the SiARC was successively performed using the single-wafer-type CCP etching apparatus used in the etching of the silicon dioxide film (first film) and the ashing of the photoresist. The processing conditions are as follows:

pressure: 1.33 Pa (10 mTorr)

high-frequency power (upper/lower electrodes): 600 W/100 W

processing gas: CF₄/Ar=100/200 sccm

time: 45.0 seconds

### Ashing of Amorphous Carbon

The ashing of the amorphous carbon was successively performed using the single-wafer-type CCP etching apparatus used in the etching of the silicon dioxide film (first film), the ashing of the photoresist and the etching of the SiARC. The processing conditions are as follows:

pressure: 3.99 Pa (30 mTorr)

high-frequency power (upper/lower electrodes): 600 W/300 W

processing gas: O₂=300 sccm

time: 60.0 seconds

### Removal of Silicon Dioxide Film (First Film) and SiARC

The removal of the silicon dioxide film (first film) and the SiARC was performed using a gas chemical etching apparatus. COR (Chemical Oxide Removal) processing and PHT (Post Heat Treatment) processing were repeated five times under the following processing conditions. The conditions of COR (Chemical Oxide Removal) processing are as follows:

pressure: 2.66 Pa (20 mTorr)

processing gas: HF/NF₂/Ar=40/40/34 sccm

temperature (upper/sidewall/lower portions): 60/60/35 degrees C.

time: 60.0 seconds

The conditions of PHT (Post Heat Treatment) processing are as follows:

pressure: 89.8 Pa (675 mTorr)

processing gas: N₂=500 sccm

temperature: 150 degrees C.

time: 60.0 seconds

### Formation of Silicon Dioxide Film (Second Film)

The formation of the silicon dioxide film (second film) was performed at a temperature of 140 degrees C. or less by the batch-type film forming apparatus and through the use of a MLD (Molecular Layer Deposition) method. The silicon dioxide film has a thickness of 12 nm.

### Etching of Silicon Dioxide Film (Second Film)

The etching of the silicon dioxide film (second film) was performed through the use of a single-wafer-type CCP etching apparatus that generates plasma by applying a high-frequency power to between an upper electrode and a lower electrode. The processing conditions are as follows:

pressure: 2.66 Pa (20 mTorr)

high-frequency power (upper/lower electrodes): 600 W/100 W

processing gas: CF₄/Ar=100/200 sccm

time: 20.0 seconds

### Ashing of Amorphous Carbon Film

The ashing of the amorphous carbon film was successively performed using the single-wafer-type CCP etching apparatus used in the etching of the silicon dioxide film (second film). The processing conditions are as follows:

pressure: 2.66 Pa (20 mTorr)

high-frequency power (upper/lower electrodes): 600 W/30 W

processing gas: O₂=350 sccm

time: 90.0 seconds

### Break-Through Processing

Subsequent to the ashing of the amorphous carbon film, break-through processing is performed by the single-wafer-type CCP etching apparatus. An oxide film and a natural oxide film attached to the surface of a semiconductor wafer were removed by ashing. The processing conditions are as follows:

pressure: 2.66 Pa (20 mTorr)

high-frequency power (upper/lower electrodes): 600 W/100 W

processing gas: CF₄/Ar=100/200 sccm

time: 5.0 seconds

### Etching of Polysilicon Layer

The etching of the polysilicon layer was successively performed using the single-wafer-type CCP etching apparatus used in the etching of the silicon dioxide film (second film), the ashing of the amorphous carbon film and the break-through processing. The processing conditions of main etching are as follows:

pressure: 1.33 Pa (10 mTorr)

high-frequency power (upper/lower electrodes): 300 W/200 W

processing gas: Cl₂/Ar/N₂=100/200/200 sccm

time: 30.0 seconds

### Over-Etching

The processing conditions of over-etching are as follows:

pressure: 3.99 Pa (30 mTorr)

high-frequency power (upper/lower electrodes): 600 W/30 W

processing gas: Cl₂/O₂/N₂=160/5/80 sccm

time: 60.0 seconds

The pattern of the polysilicon layer of the example formed under the processing conditions noted above was observed with an electronic microscope. This observation revealed that a line-and-space pattern having a pitch equal to ¼ of the initial photoresist pattern is formed.

A mask (cut mask) for cutting the pattern may be formed by a photoresist on the line-and-space pattern thus obtained. If necessary, shrinking may be performed by use of an insulating film. Using the mask, the line-and-space pattern may be patterned into a desired pattern.

According to the present embodiment described above, it is possible to provide a semiconductor device manufacturing method capable of accurately forming a desired fine pattern in a more efficient manner than in the prior art and capable of enhancing the production efficiency of a semiconductor device.

While one embodiment has been described, this embodiment has been presented by way of example only, and is not intended to limit the scope of the disclosures. Indeed, the novel method described herein may be embodied in a variety of other forms; furthermore, various omissions, substitutions and changes in the form of the embodiment described herein may be made without departing from the spirit of the disclosures. The accompanying claims and their equivalents are intended to cover such forms or modifications as would fall within the scope and spirit of the disclosures.

What is claimed is:

1. A semiconductor device manufacturing method, comprising:
forming a core layer, an anti-reflection film and a photoresist layer on a layer to be etched of a substrate with the core layer below the anti-reflection film and the photoresist layer over the anti-reflection film, the photoresist layer being patterned into first line patterns aligned at a desired interval;
trimming the first line patterns of the photoresist layer;
forming a first film on the first line patterns of the trimmed photoresist layer;
removing the first film such that the first film is left in sidewall portions of the first line patterns of the photoresist layer;
removing the photoresist layer;
producing the core layer into second line patterns by etching the anti-reflection film and the core layer using the first film as a mask;
forming a second film on the core layer produced into the second line patterns;
removing the second film such that the second film is left in sidewall portions of the second line patterns of the core layer; and
producing the layer to be etched into third line patterns by etching the layer to be etched using the second film as a mask.

2. The method of claim 1, wherein the core layer is formed of a carbon film.

3. The method of claim 2, wherein the carbon film is made of amorphous carbon.

4. The method of claim 2, wherein the carbon film is formed of a coating film.

5. The method of claim 1, wherein the first film and the second film are formed at a temperature of 140 degrees C. or less.

6. The method of claim 1, further comprising:
forming a patterned photoresist mask on the third line patterns of the layer to be etched; and
patterning the third line patterns of the layer to be etched by etching the layer to be etched through the photoresist mask.
